(19) United States
(12) Patent Application Publication
(10) Pub. No.: US 2006/0202104 A1
(43) Pub. Date: Sep. 14, 2006

(54) Contact-type monolithic image sensor

(75) Inventors: Igor Gurevich, Saarbrucken (DE); Victor Faybishenko, San Carlos, CA (US); Leonid Velikov, San Carlos, CA (US)

Correspondence Address: Leonid Velikov, 1371 Greenbrier Rd, San Carlos, CA, 94070, US

(73) Assignee: Microalign Technologies, Inc.

(21) Appl. No.: 11/079,549

(22) Filed: Mar. 14, 2005

(51) Int. Cl. H01L 27/00

(52) U.S. Cl. 250/208.1

(57) ABSTRACT

A thin monolithic image sensor of the invention is comprised of a laminated solid package composed essentially of an optical layer and an image-receiving layer placed on the top of the optical layer. The optical layer also comprises a laminated structure composed of at least an optical microlens-array sublayer and an aperture-array sublayer. The image-receiving layer is a thin flat CCD/CMOS structure that may have a thickness of less than 1 mm. The image digitized by the CCD/CMOS structure of the sensor can be transmitted from the output of the image-receiving layer to a CPU for subsequent processing and, if necessary, for displaying. A distinguishing feature of the sensor of the invention is that the entire sensor along with a light source has a monolithic structure, and that the diaphragm arrays are located in planes different from the plane of the microlens array and provide the most efficient protection against overlapping of images produced by neighboring microlenses.

### CROSS-REFERENCE TO RELATED APPLICATIONS

not applicable

### FEDERALLY SPPONSORED RESEARCH

not applicable

### SEQUENCE LISTING OF PROGRAM

not applicable

### BACKGROUND OF THE INVENTION—FIELD OF INVENTION

The present invention relates to monolithic optical image sensors, in particular to contact-type monolithic optical image sensors for precision measurement of configurations, shapes, and dimensions of flat objects or flat parts of the objects that are in contact with the aforementioned sensors. The image sensors of the invention may find use in the manufacture of miniature and precision parts, for sorting precision parts, as well as for identification of various parts and objects in open, as well as in hard-to-get areas, such as thin slots, e.g., of banking automatic teller machines. Another possible application is for security purposes, e.g., identification of biometric images, such as fingerprints, signatures, or the like, in combination with coded data.

### BACKGROUND OF THE INVENTION—PRIOR ART

In spite of the recent progress in the field of machine vision and image sensing, a number of problems still remain unsolved. An example of such problems is rapid reading of super-fine bar codes on miniature parts. This is because conventional bar-code readers have a limited resolution capacity. On the other hand, there is a continuous demand for coding fine and super fine parts, e.g., for identification purposes.

Furthermore, there is an ever-growing application for machine vision and image sensing products in the field of security, especially, for reading various biometric data, e.g., fingerprints, personal signatures, etc.

Although the following description will further concern the problems associated with reading biometric data, the same concept should be considered in a broader sense to cover data of other types used for identification of objects with the application of machine vision devices.

One of the most popular methods for identification of a human being is recording and reading his/her fingerprints. There exist a plurality of methods and devices for accomplishing the aforementioned task. Some of these methods and devices are described by Davide Maltoni, et al. in “Handbook of Fingerprinting Recognition”, Springer-Verlag N.Y., Inc, 2003.

An example of a known fingerprint-sensing device is shown in FIG. 1. The device 20 consists of a glass prism 22, one face 24 of which is intended for physical contact with the surface of an object, such as a bar-code image, small part, signature on a paper, fine marks, or person's fingerprint. The surface 24 of the prism in contact with the aforementioned prism face 24 is illuminated from a source of light 26 through another face 28 at an angle that does not exceed the total internal reflection angle. The light reflected from the face 24 passes through the third face 30 of the prism 20 and via an optical objective 21 to an image-receiving element 32 such as a CCD (charge-coupled device) or a CMOS (complementary metal-oxide semiconductor structure). The device 20 shown in FIG. 1 is also known as a FTIR (Frustrated Total Reflection)-type device. When the finger F touches the top side 24 of the glass prism 22, the ridges of the pattern on the surface of the finger F enter in contact with the prism surface 24, while valleys remain at a certain distance. This distorts conditions of reflection, and the distortion is used for imaging the fingerprint. The light source 26 of such an imaging device 20 may be comprised, e.g., of a LED (light-emitting diode).

It is obvious that the dimension of the contact surface 24 of such an image sensor 20, which is directly associated with the sensor height, determines the overall dimensions of the sensor 20 as a whole, i.e., the sensor of this type is a three-dimensional device. For example, even if the contact surface 24 of the sensor 20 is as small as 1.5 cm², the height of the sensor 20 cannot be less than 10 mm. Furthermore, resolution of the FTIR sensor 20 will to a great extent depend on the quality of the objective 21 that projects the reflected image onto the image-receiving element 32. In other words, in order to ensure resolution of about 5 μm, the device 20 has to be provided with a sufficiently precision microscopic objective 21. Such an objective may be a rather bulky and relatively expensive device that will make the entire image-sensing device 20 large and expensive.

There exist many other models of FTIR systems that are aimed at improvement of their performances. For example, FIG. 2 illustrates a FTIR-type image sensing device 34 that allows decrease of the sensor's height. The device 34 is characterized by the use of a sheet prism 36 composed of a plurality of small prisms 38a, 38b, . . . 38n (known as “prismlets”) arranged adjacent to each other. The top side of the sheet prism 36 is brought in contact with the finger F1. Even though the total height (which hereinafter will be referred to as “Z-dimension” of the device) can be reduced to some extent, the system of FIG. 2 still requires the use of a bulky image-receiving optical system (not shown in FIG. 2), so that the total Z-dimension of the image-sensing device 34 remains significant.

FIG. 3 illustrates an image-sensing device that has a reduced Z-dimension. The device 40 shown in this drawing is based on the use of a micro-channel plate 42 that is comprised of a plurality of optical fibers arranged in the Z-axis direction. The micro-channel plate 42 is laminated with a plate-like CCD/CMOS image sensor 44. Since the package of plates 42 and 44 does not allow use of an external light source for illuminating the surface of the finger F2, the device 40 utilizes a residual light that penetrates the fingerprint valleys through the peripheral openings formed between the contact surface 46 of the micro-channel plate 42 and the surfaces of the fingerprint valleys that are open to the external light through the periphery of the contact area. The light reflected from the surface being analyzed enters individual optical fibers of the micro-channel plate 42 through the angle of total internal reflection and propagates through the fibers to the CCD/CMOS 44 so that a pixeled image with the number of pixels corresponding to the number of the optical fibers is obtained. It is obvious that the lack of direct illumination of the finger surface significantly lowers image-recognition capacity of the device. For example, such a device cannot reproduce an image on the flat surface of the object, e.g., a signature written on a flat card, etc.

In spite of the fact that the idea of compacting the sensing and image-receiving flat and thin elements into a monolithic sensor is rather attractive, such known devices as shown in FIG. 3 did not find commercial application in view of disadvantages inherent in these devices.

Attempts have been made to solve the light-delivery problem in the devices of the type shown in FIG. 3. An example of a monolithic image-recognition package 48 with improved light-delivery system is shown in FIG. 4. The device 48 has two main layers. The first layer 50 contains a polymer that, when polarized with the proper voltage, emits light that depends on the potential applied on one side (shown by the arrow on the right side in FIG. 4). As ridges of the fingerprint 52a, 52b, . . . 52n touch the polymer and the valleys 54a, 54b, . . . 54n do not, the potential is not the same across the surface when a finger F4 is placed on it, and the amount of light emitted varies, and thus allows a luminous representation of the fingerprint pattern to be generated. A second layer 56, strictly coupled with the first one, consists of a light-receiving element, e.g., CCD/CMOS, which is responsive for receiving the light emitted by the polymer and converting it into a digital image. However, in spite of great miniaturization, images produced by the aforementioned device are not comparable in quality, e.g., with FTIR images.

Known in the art also are monolithic imaging sensors of non-optical type, such as capacitive image sensors, thermal image sensor, electric-field sensors, piezo-electric sensors, which are also described in the aforementioned handbook of Davide Maltoni. Such sensors are based on converting some physical characteristics of the pattern to be reproduced into electrical signals that are later converted into images that correspond to the target surface being analyzed. However, none of these non-optical image sensors found practical commercial use for the reasons described in the aforementioned handbook.

Thus, until now a demand for a miniature image sensor that could combine small overall dimensions with high resolution capacity and high contrast of reproduced images remains actual.

In general, each image sensor consists of a number of elements. For example, as has been shown above, an optical image sensor consists of an optical part that contains a light source, light-delivery means, and image-forming unit, and an image-receiving part that normally consists of well-developed CCD/CMOS devices that are being constantly improved. It is understood that one way of miniaturization of optical image sensors is improvement and miniaturization of specific optical elements in the structure of the optical sensor.

In this connection, the applicants of the present patent application have developed a flat wide-angle lens system intended for creating images with an extremely wide angle of observation. This system (that is disclosed in U.S. patent application Ser. No. 10/862,178 filed on Jun. 7, 2004 by Igor Gurevich, et al.) consists of a first component, which is intended for reduction of the field angle of light incidence onto the objective and comprises an assembly of at least two microlens arrays having the same pitch between the adjacent microlenses and arranged with respect to each other so as to provide a focality, and a second component that comprises an assembly of conventional spherical or aspherical microlenses that create an image on an image receiver. Each two coaxial microlenses of the microlens arrays of the first component form an inverted microtelescope of Galileo. The outlet aperture of a single microtelescope is made so that spherical aberrations can be minimized almost to zero, while field aberrations can be corrected by design parameters of the microlenses. The use of such an array of microtelescopes makes it possible to significantly reduce overall dimensions of the first component of the lens system since the longitudinal dimension of a unit telescopic cell of the array is much smaller than the longitudinal dimension of a conventional lens component used for the same function.

Another optical system that may exemplify the aforementioned approach is a miniature objective developed by the same applicants and disclosed in pending U.S. patent application Ser. No. 10/893,860 filed by Igor Gurevich, et al. on Jul. 19, 2004. This objective consists of a first sub-unit that is located on the object side of the objective and comprises an assembly of two conventional aspheric negative, e.g., aspheric plano-concave lenses, and a second sub-unit in the form of a set of four microlens arrays arranged on the image-receiving side of the objective. The microlenses of all microlens arrays have the same arrangement of microlenses in all the arrays. A diaphragm array with restricting openings can be sandwiched between a pair of the microlens arrays. The objective of the aforementioned patent application can be realized into an optimal design only with predetermined relationships between the parameters of the optical system that forms the objective. The aforementioned invention makes it possible to drastically reduce the longitudinal dimension of the objective. In operation, the first sub-unit creates an imaginary image of the object in its focal plane, which is located on the object side of the objective, while the second sub-unit creates an actual image of the object in the image plane on the image-receiving side of the objective. In this case, the function of the object plane is fulfilled by the aforementioned focal plane of the first sub-unit that contains the imaginary image of the real object.

In both examples given above, the overall longitudinal dimensions of the optical system were drastically reduced by replacing a part of conventional lenses with thin flat microlens arrays or their combinations. As a result, the last-mentioned objective may have the length in the direction of the optical axis as small as 5 mm with the transverse dimension limited only by the size of the image-receiving unit.

Another example of miniaturization of an image-forming and image-receiving package is disclosed in International Patent Application Publication No. WO 00/64146 A3 published on Oct. 26, 2000 (Filed Apr. 20, 2000, Inventor—Reinhard Volkel, et al.). The Volkel's et al. invention relates to a flat image acquisition system, which has a lens matrix array containing a plurality of adjacent microlenses. The system also comprises a flat photodetector array, which in the optical path is positioned in an image plane behind the microlenses. In such a device that can be used, e.g., in a flat photo camera, the distance between the front of the lens matrix array and the sensitive surface of the photodetector array may be less than 10 mm, e.g., less than 5 mm.

However, a disadvantage of the Volkel's et al. device is that it comprises a system of thin microlens arrays that are separated by air gaps and therefore cannot be considered as a monolithic structure. Furthermore, since diameters of microlenses are normally within the range from hundreds of microns to several millimeters, focal distances also do not exceed hundreds of microns. Therefore the depth of focus is expected to be in the order of tens of microns. It is understood that optical aligning and assembling of such a structure present a difficult technical problem.

Furthermore, the aforementioned wide-angle objective, as well as the Volkel at al.'s system are intended for use, e.g., in photographic cameras where the object plane is remotely located from the image plane and is not applicable for contact-type image-forming device where, from optical point of view, the object plane and the physical front plane of the sensor coincide. In other words, when the object is a fingerprint, a finger normally rests on the front plane of the sensor, e.g., on the prism face from which the fingerprint image is reflected into the CCD/CMOS of a FTIR device.

It should be noted that in photography an image is formed by light rays reflected from illuminated objects. In other words, objects can be easily illuminated by external light sources, such as sun rays, artificial light, etc. However, in devices as above-described contact image sensors the object should be in physical contact with the front surface of the sensor. Therefore, conventional methods of delivery of light to the surface of the object become inapplicable. Such systems require non-trivial methods for delivery of light to the surface of the object. In this context, the term “non-triviality” means that the light from the light source has to be delivered to the surface of the object but is prevented from direct incidence onto the image-receiving surface. Until now such light-delivery systems have been unknown.

It can be summarized that, although the system described in the aforementioned international patent application, as well in other references are good examples of the current trend to miniaturization of image-forming and image-receiving packages, the aforementioned trend is limited by complexity of manufacturing and assembling, as well as by the lack of standardized elements and sub-assemblies that otherwise could be used for assembling systems different in their purposes.

### SUMMARY OF THE INVENTION

It is an object of the invention to provide a thin flat monolithic image sensor that has a thickness reduced to the dimension unattainable in conventional flat image sensors. It is another object to provide a thin flat monolithic image sensor having a thin-layered laminated structure that consists of an optical layer and an image-receiving layer, wherein the optical layer incorporates a light source for illumination of the sensor's surface that is in contact with an object the image of which is to be reproduced. It is another object to provide the flat monolithic sensor, wherein the aforementioned thin-layered laminated structure is assembled from identical standardized modular elements. It is an object of the present invention to provide a thin monolithic image sensor that may have a total thickness not exceeding 2.5 mm and is intended for receiving and forming an image of an object brought in contact with the external surface of the aforementioned optical layer. It is a further object to provide a thin flat monolithic image sensor of the aforementioned structure wherein light emitted by the light source propagates only towards the object, while the light reflected from the surface that is in contact with an object or that is scattered after being reflected from that surface propagates only towards the light-receiving layer. A further object is to provide a thin flat monolithic image sensor suitable for reproducing images of fingerprints. Another object is to provide a flat monolithic image sensor of a laminated structure that has a simplified construction consisting of a combination of identical layers. A still another object is to provide a flat monolithic image sensor of a laminated structure, wherein all the layers are formed substantially of the same material.

A thin monolithic image sensor of the invention is comprised of a laminated solid package composed essentially of an optical layer and an image-receiving layer placed on the top of the optical layer. The optical layer also comprises a laminated structure composed of at least an optical microlens-array sublayer and an aperture-array sublayer. The optical microlens-array sublayer is made of an optically transparent material that passes light of a predetermined wavelength and is comprised of a plurality of equally spaced microlenses. Examples of the aforementioned material are polymer, glass, quartz, silicon, or other materials that allow formation of microlens array matrices, e.g., by photolithography, molding, etc. The optical microlens-array sublayer may have a thickness as small as several ten microns. Dimension in the plane of this sublayer in the X-Y plane is not limited and is defined by the dimensions of the aforementioned image-receiving layer. The latter is a thin flat CCD/CMOS structure that may have an area in the X-Y plane up to several ten square centimeters and is limited only by the dimensions of modern semiconductor wafers. The image-receiving layer may have a thickness of less than 1 mm. The sandwich composed of the optical and image-receiving sublayers form a flat, very thin image sensor that may have a total thickness not exceeding 2.5 mm and is intended for receiving and forming an image of an object brought in contact with the external surface of the aforementioned optical layer. The image digitized by the CCD/CMOS structure of the sensor can be transmitted from the output of the image-receiving layer to a CPU for subsequent processing and, if necessary, for displaying. Since the image sensor of the invention is a contact-type sensor, and illumination of the portion of the upper side of the optical layer which is in contact with the object is blocked for the external light, the sensor is provided with an internal or built-in light source for illuminating the surface in contact with the object being reproduced. The aforementioned microlens-array sublayer is structured so that the light emitted by the light source illuminates only the areas in contact with the object and is prevented from falling onto the image-forming layer, while only the light reflected and/or scattered from the surface in contact with the object can pass through the microlens-array sublayer to the CCD/CMOS structure. The image sensor of the invention is described in two embodiments. In one embodiment, a light source (sources) is (are) located on the lateral side (sides) of the optical layer for illuminating the surface of the object. In the second embodiment the light source is made in the form of a single or a multiple light-emitting diode source embedded into the laminated optical layer. The structure of the system of the invention is based on the use of two or more standard modular units that can be interchangeable between different models or repeatedly used in the same assembly.

### DRAWINGS—FIGURES

FIG. 1 is a schematic view of a known fingerprint-sensing device of a frustrated total reflection-type device (FTIR type).

FIG. 2 is a schematic view of a known FTIR-type image-sensing device that allows decrease of the sensor's height.

FIG. 3 illustrates a known image-sensing device that has a reduced Z-dimension.

FIG. 4 is an example of a known monolithic image-recognition package with an improved light-delivery system.

FIG. 5 is a simplified schematic view of a thin monolithic image sensor according to an embodiment, in which a light source is located on the lateral side of the optical layer for illuminating the surface of the object.

FIG. 6 is a simplified schematic view of a thin monolithic image sensor according to an embodiment, in which a light source is made in the form of light-emitting diodes embedded into the laminated optical layer.

FIG. 7 is a schematic sectional view of an embodiment of the sensor with a lateral light source.

FIG. 8 is a sectional view of a laminated optical layer used in the embodiment of the image sensor of FIG. 7.

FIG. 9A is a top view of a microlens array in the optical layer of FIG. 8 that shows a hexagonal and compact round arrangement of microlenses.

FIG. 9B is a top view of a microlens array in the optical layer of FIG. 8 that shows an orthogonal arrangement and compact round arrangement of microlenses.

FIG. 10 is an optical scheme that shows optical paths of light rays passing through elemental optical systems formed in the optical layer of FIGS. 7-9 by individual coaxially arranged holes of the first aperture-limitation diaphragm array, microlenses of the first microlens array, microlenses of the second microlens array, holes of the field-limitation diaphragm array, microlenses of the third microlens array, microlenses of the fourth array, and holes of the second aperture-limitation diaphragm array.

FIG. 11 is a view of a master die for manufacturing microlenses of the optical layer shown in FIGS. 7-10.

FIG. 12 is a view that illustrates the structure of an optical layer of the sensor with a light source in the form of light-emitting diodes embedded into the laminated optical layer.

FIG. 13 is an example of a planar light source for the image sensor of FIG. 12.

FIG. 14 is a vertical sectional view of the light source of FIG. 13.

FIG. 15 is a fragmental sectional view of the planar light source that is based on the use of organic light-emitting diodes (OLED).

FIG. 16 is a three-dimensional view of a part of the light source formed by the structure of FIG. 15.

FIG. 17 is a sectional view of an optical layer of a thin monolithic image sensor that has a simplified construction and less expensive to manufacture.

FIG. 18 is a three-dimensional view of the microlens array of the sensor of FIG. 17 seen from the microlens side.

FIG. 19 is a three-dimensional view of the aperture-limitation diaphragm array that shows an arrangement of the round projections in the aforementioned diaphragm array.

FIG. 20 is a view that shows an arrangement of square projections of the field-limitation diaphragm array used in the optical layer of FIG. 17.

FIG. 21 shows optical paths of light rays passing through the laminated optical layer of FIG. 17, where the light propagates from the planar light source towards the object-contact surface in the direction of arrow A3, while the light reflected from the surface of the aforementioned sensor propagates towards the image-receiving layer.

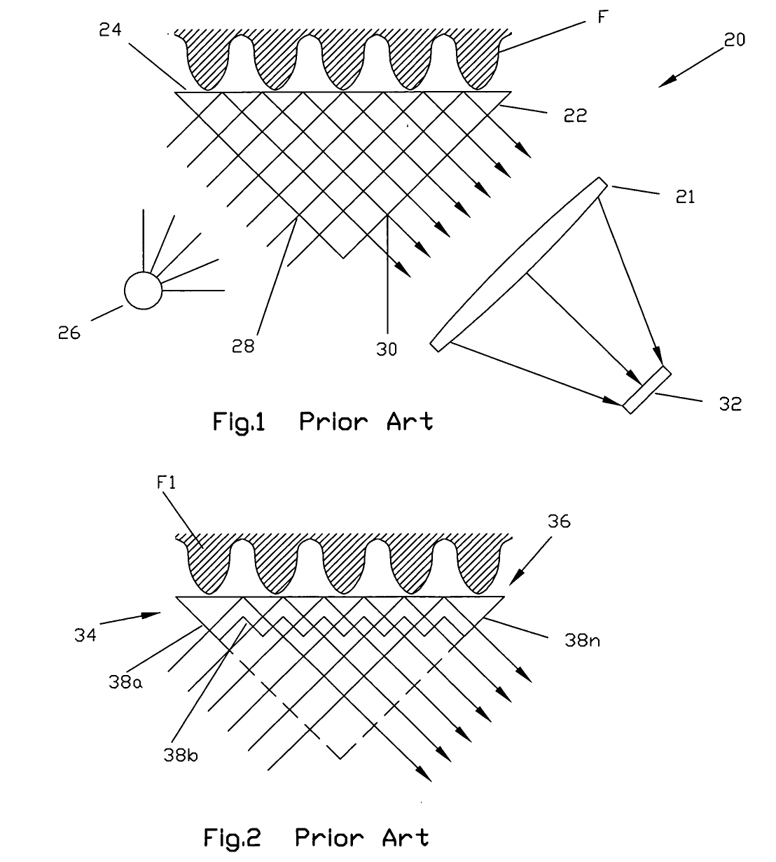

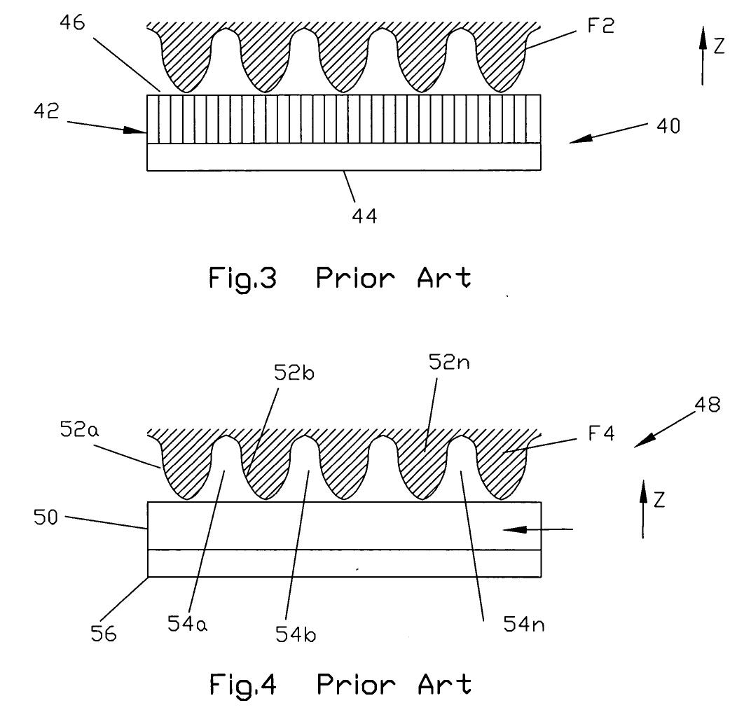

### DRAWINGS—REFERENCE NUMERALS

20—known fingerprint-sensing device
22—glass prism
24—prism face for contact with a finger
26—light source
28—second face of the prism
30—third face of the prism
32—image-receiving element
34—FTIR-type image sensing device
36—sheet prism composed of a plurality of small prisms
38a, 38b, . . . 38n—prismlets
40—image-sensing device
42—microchannel plate
44—plate-like CCD/CMOS image sensor
46—contact surface
48—monolithic image-recognition package
50—polymer layer of device 48
52a, 52b, ,,,52n—ridges of a fingerprint
52a, 52b, ,,,52n—valleys of a fingerprint
56—second layer of the device 48
120a—image sensor of the invention according to the embodiment with a lateral light source
120b—image sensor of the invention according to the embodiment with an interlayer light source
122a, 122b—light sources
124a, 124b—optical layers
124a, 124b—image-receiving layers
130—monolithic image sensor
132—optical layer
134—image-receiving sensor
136a, 136b—identical optical units
138, 138′—silicone oxide sublayers
140, 140′—aperture-limitation diaphragms
140a, 140b, . . . 140n, 140a′, 140b′, . . . 140n′—holes of the aperture—limitation diaphragms 140, 140′
142, 142′—silicone oxide sublayer
144, 144′—microlens arrays
136a, 136b—identical units of the optical layer 132
138, 138′—silicon oxide sublayers
140, 140′—aperture-limitation diaphragm arrays
140a, 140b, . . . 140n, 140a′, 140b′, ,,, 140n′—diaphragm holes
142, 142′—silicon oxide sublayers
144, 144′—microlens arrays
144a, 144b, . . . 144n, 144a′, 144b′, . . . 144n′—microlenses
146, 146′—separation sublayers
148, 148′—microlens arrays
150, 150′—mating sublayers of two stacked optical units 136a and 136b
152—field-limitation diaphragm between optical units 136a and 136b
152a, 152b, . . . 152n—holes of the field-limitation diaphragm 152
154—master die
160, 162, 164—three units produced in the manufacture of the optical layer 132
236—optical unit with a planar light source
240—aperture-limitation diaphragm array in the embodiment with a planar light source
238′—silicone oxide sublayer
240′—planar light source
240a, 240b, . . . 240n, 240a′, 240b′, . . . 240n′—hole of aperture-limitation diaphragms
242, 242′—silicon oxide sublayers
244′—microlens array
260—unit of an optical layer in the embodiment with the planar light source
270, 272—electrical contacts
272a, 272b—terminal busses
274—laminated light-emitting structure
274a, 274b, . . . 274n—light-emitting sublayer
276a, 276b, . . . 276n—slots
300—light source based on the use of OLEF
302—metallic cathode layer
302a—blackened side of the layer 302a
304-electron injection layer
306—electron transfer layer
308—emission material layer
310—hole-transfer layer
312—protective glass layer
314—anode layer
316—aperture-limitation diaphragm array
316a, 316b, . . . 316n—aperture-limitation diaphragm holes
400—optical layer in an image sensor of another modification
402, 402′—two identical pairs of optical units
404, 406—microlens arrays
404a, 404b, . . . 404n, 406a, 406b. . . 406n—microlenses
410—spacing polycarbonate sublayer
405a, 405b, . . . 405n and 407a, 407b, . . . 407n—parallel mutually perpendicular rows of the ridges
409—blackened surface
409a, 409b. . . 409n—optical spacers
408—aperture-limitation diaphragm array
412—optical spacer
414—field-limitation diaphragm array
414a, 414b, . . . 414n—projections
416a, 416b, . . . 416n—projections
418—optical spaces

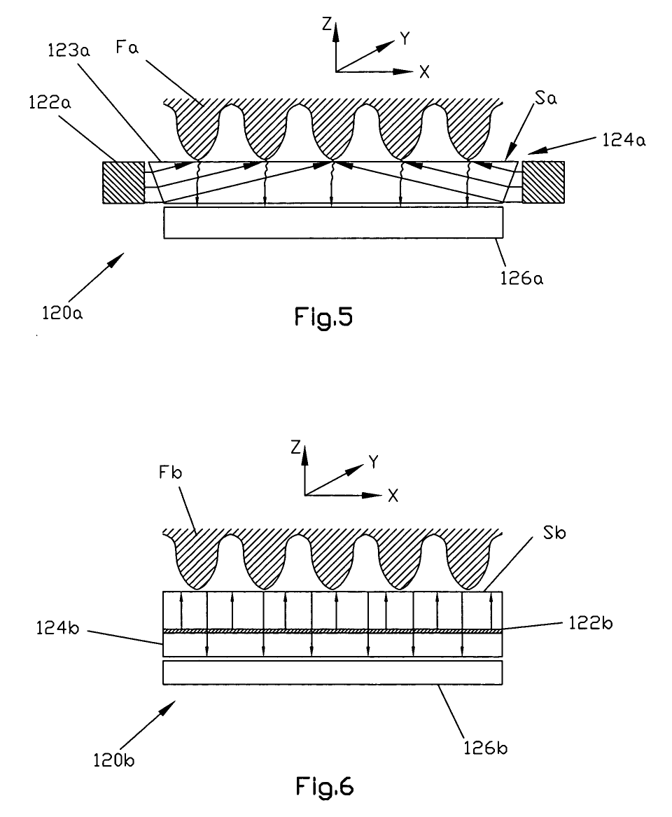

### DETAILED DESCRIPTION—PREFERRED EMBODIMENTS—FIGS. 5-16

General Features of Two Embodiments

In general, the sensor of the invention can be realized in two different embodiments. Although the principle of the invention is common for both embodiments, each embodiment can be realized in several slightly different modifications. In one preferred embodiment of a sensor 120a, a schematic sectional view of which is shown in FIG. 5, a light source (sources) 122a is (are) located on the lateral side (sides) of the optical layer for illuminating the inner top surface of the glass plate which is in contact with the object. In the second preferred embodiment of a sensor 120b, which is schematically shown in cross section in FIG. 6, an interlayer light source 122b is made in the form of a single or a multiple light-emitting diode source embedded into the laminated optical layer. The subsequent description of parts and elements that are identical in both sensors 120a and 120b (FIG. 5 and FIG. 6) will be related to both embodiments at the same time. In FIGS. 5 and 6 these parts and elements will be designated by the same reference numerals with the addition of symbols “a” and “b”, respectively. Common parts of both sensors will be described with reference to the sensor 120a only, while reference numerals of the identical parts of the sensor 120b will be indicated in parentheses.

A monolithic image sensor 120a (120b) of the invention is comprised of a laminated solid package composed essentially of an optical layer 124a (124b) and an image-receiving layer 126a (124b) placed on one side (the lower side in FIGS. 5 and 6) of the optical layer 124a (124b). The optical layer 124a (124b) also comprises a laminated structure, which will be described for each embodiment in more detail later. The aforementioned image-receiving layer 124a (124b) is a thin flat CCD/CMOS structure. Such CCD's and CMOS's are produced by many companies, e.g., by Eastman Kodak Company, U.S.A.

The sandwich composed of the optical and image-receiving sublayers 124a (124b) and 124a (124b) forms a flat, very thin image sensor having a thickness not exceeding 2.5 mm.

The thin flat CCD/CMOS structure is intended for receiving and forming an image of an object, e.g., fingerprints of a finger Fₐ (F_{b}) brought in contact with the external surface Sₐ (S_{b}) of the aforementioned optical layer 124a (124b). An image digitized by the CCD/CMOS structure of the sensor 120a (120b) can be transmitted from the output of the image-receiving layer 124a (124b) to a CPU (not shown in FIGS. 5 and 6) for subsequent processing and, if necessary, for displaying. Since the image sensor of the invention is a contact-type sensor and illumination of the object in contact with the upper side Sₐ (S_{b}) of the optical layer 124a (124b) by external light is impossible, the sensor is provided with a built-in light source 122a (122b) for illuminating the surface of the object being reproduced.

Arrangement of the light sources 122a (122b) constitutes the aforementioned difference between the embodiments of FIGS. 5 and 6 and will be described in more detail later in separate consideration of both embodiments. More specifically, in the embodiment of FIG. 5, the light source 122a is located on a lateral side (sides) of the optical layer 124a for illuminating the surface of the object Fₐ. In the embodiment of FIG. 6, the light source 122b is made in the form of a single or a multiple light-emitting diode source embedded into the laminated optical layer 124b.

A unique feature of the sensors 120a and 120b of both embodiments (FIG. 5 and FIG. 6) is that the structure of the optical layer allows illumination only of the surface in contact with the object Fₐ (F_{b}) and prevents the illumination light from falling onto the image-forming layer 124a (124b), while only the light reflected from the surface of the object Fₐ (F_{b}) (or scattered after reflection) can pass through the optical layer 124a (124b) to the image-forming layer, i.e., to the CCD/CMOS structure 124a (124b).

Preferred Embodiment of a Sensor with a Lateral Light Source—FIGS. 5, 7-11

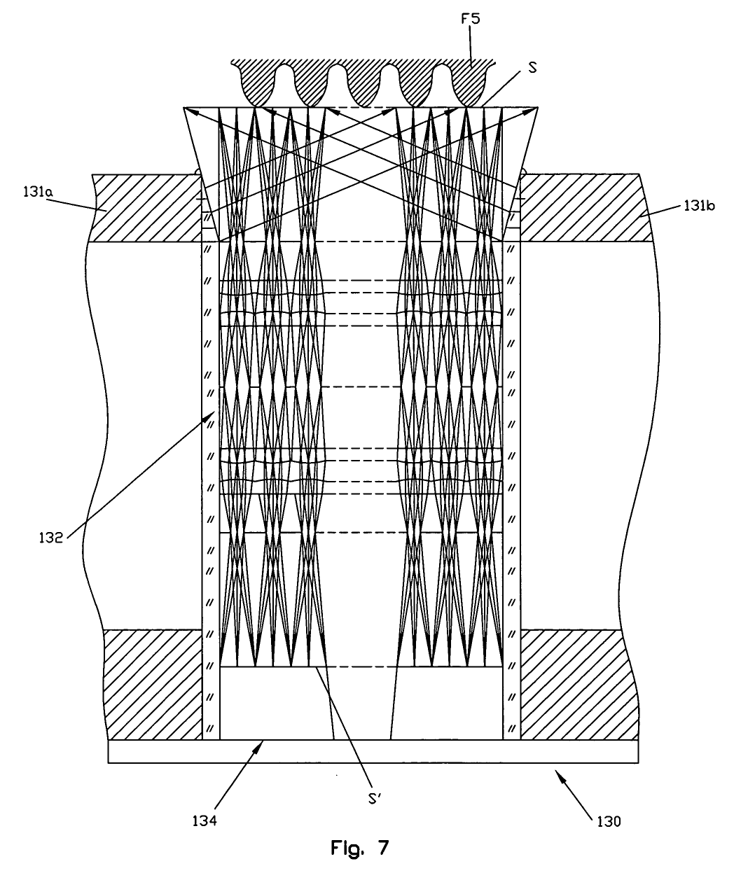

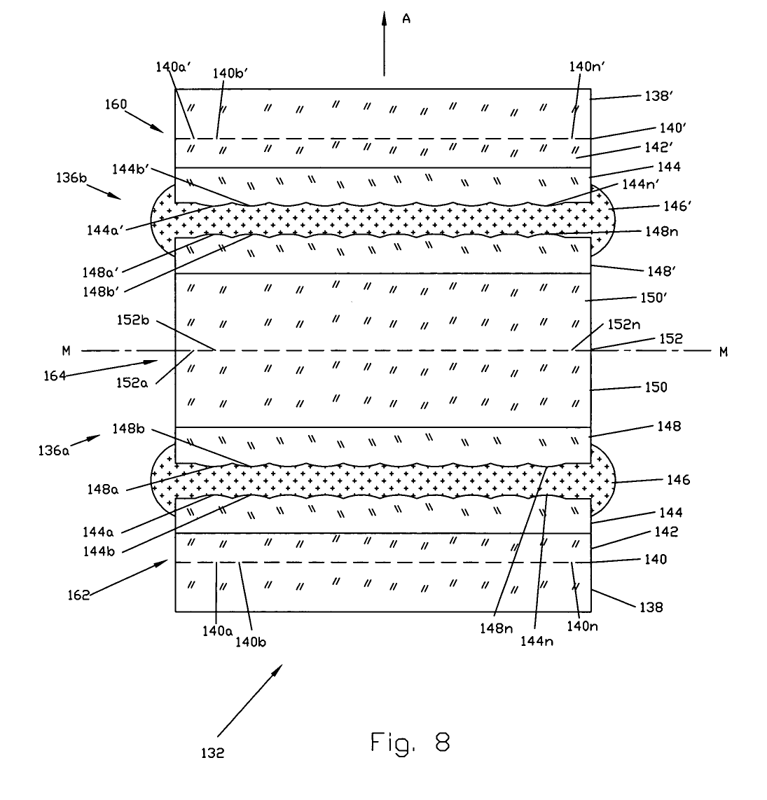

As has been mentioned in the common description of both embodiments, a thin monolithic image sensor 130 of the invention is comprised of a laminated solid package composed essentially of an optical layer 132 and an image-receiving layer 134 placed on one side (the bottom side S′ in FIG. 7) of the optical layer 132. The structure of the optical layer 132 is shown in FIG. 8, which is a sectional view of the layer. As can be seen from FIG. 8, the optical layer 132 also has a multiple-layered structure that geometrically can be considered as composed of two identical units 136a and 136b that can be considered as standard modular units arranged with mirror symmetry relative to plane M-M (FIG. 8), which coincides with plane X-Y (FIGS. 5 and 6). Since both modular units 136a and 136b are geometrically identical, the following description will refer only to unit 136a, and parts, and elements of the unit 136b that are identical with those of the unit 136a will be designated in FIG. 8 by the same reference numerals but with an addition of a prime.

The unit 136a consists of the following sublayers described below in the direction towards the unit 136b. It is understood that all below-described sublayers are made from transparent light-permeable optical materials of high transmissivity, such as glass, quartz, polymers, transparent optical glues, etc.

The first sublayer is a sublayer 138, which is intended to be in contact with the image-receiving layer 134 (FIG. 7). In the specific example of the invention shown in FIGS. 7 and 8, the sublayer 138 comprises a thin film of 380 μm in thickness made from silicon oxide (SiO₂).

The second sublayer is an aperture-limitation diaphragm array that is also known as an aperture stop array 140. This sublayer is made of a material non-permeable to light, such as, e.g., blackened copper, and has a plurality of specifically arranged holes 140a, 140b, . . . 140n for passing the light. A total surface area occupied by the holes 140a, 140b, . . . 140n (and hence by the holes 140a′, 140b′, . . . 140n′) does not exceed 20-25% of the total area of the interface surface between the sublayers 138 and 142. Exact dimensions of the diaphragms can be calculated by ray-tracing modeling taking into account specific optical characteristics of optical elements and materials from which these elements are made.

The third sublayer 142 is also a thin transparent layer, which in the example of FIG. 8 is made from silicon oxide (SiO₂). Although geometrically this sublayer is located on the top of the aperture-limitation diaphragm array 140, in the manufacturing procedure, which will be described later, the aperture-limitation diaphragm array 140 may be formed on the third sublayer 142, e.g., by methods of photolithography. The third sublayer may have a thickness of about 100 μm.

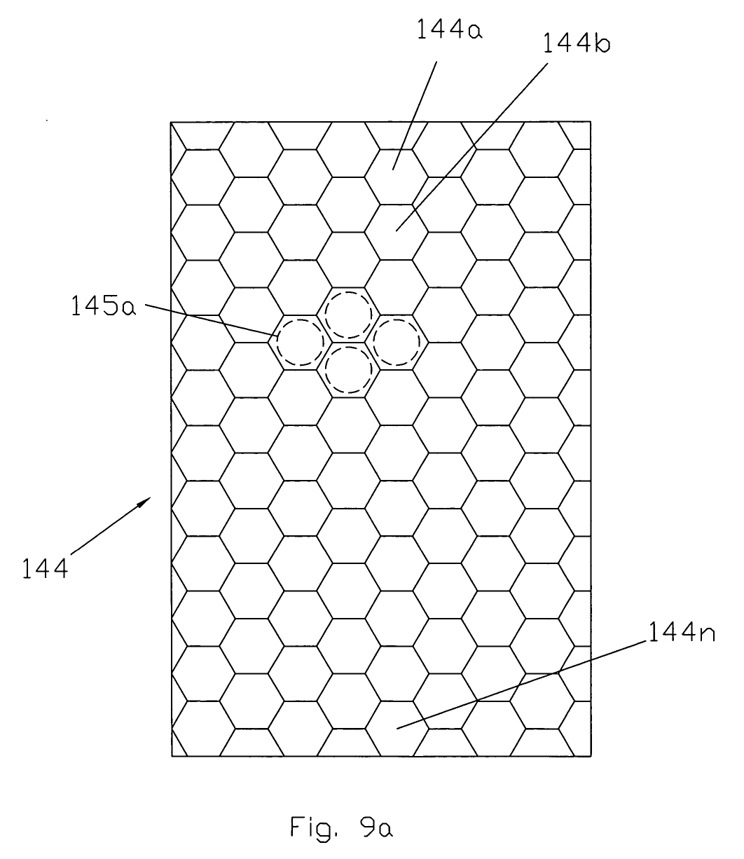

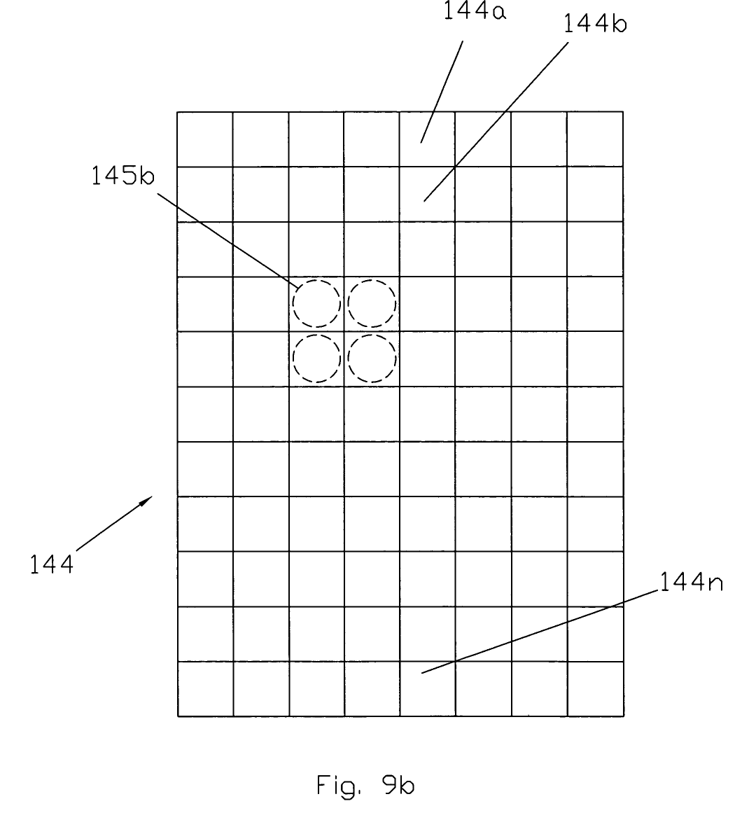

The fourth sublayer is a microlens array 144 that consists of a plurality of individual microlenses 144a, 144b, . . . 144n, which are optically coaxial with the respective holes 140a, 140b, . . . 140n of the aperture-limitation diaphragm array 140. The microlens array may have a thickness of about 100 μm. The arrangement of microlenses 144a, 144b, . . . 144n in the microlens array 144, when viewed in the direction of an optical axis indicated by arrow A in FIG. 8, is shown in FIG. 9A and 9B, where FIG. 9A shows a hexagonal arrangement, and FIG. 9B shows an orthogonal arrangement. For the sake of the simplicity of the description, both the orthogonal and hexagonal microlenses of FIGS. 9A and 9BH are designated identically as microlenses 144a, 144b, . . . 144n. The microlens array 144 is made of a transparent optical material suitable for processes of vacuum thermal sputtering deposition. In the illustrated embodiment the microlens array is made from chalcogenide glass or another material that has a very high index of refraction n (for a wavelength of about 546 nm, n is about 2.50).

The microlens arrangement is not necessarily hexagonal or orthogonal, and the microlenses may be round and packed into a dense structure, both hexagonal or orthogonal, with mostly dense arrangement so that the circular microlenses 145a and 145b are in contact with each other as shown by broken lines in FIGS. 9A and 9B, respectively.

The fifth sublayer 146 is a separation sublayer, which is made e.g., of a polymethylmethacrylate (PMMA) and is intended for separating the microlens array 144 from another microlens array 148, which forms the sixth sublayer and is identical to the microlens array 144. At a wavelength of about 546, the PMMA has an index of refraction about n=1.49. The microlens array 148 is arranged with mirror symmetry relative to the microlens array 144. In other words, the separation sublayer 146 is sandwiched between two oppositely arranged symmetrical sublayers 146 and 148.

The seventh sublayer 150 and the eight sublayer 150′ are identical, made from a transparent material, which in the illustrated embodiment is silicon oxide, and are stacked one onto the other via a field-limitation diaphragm 152 that is sandwiched between the sublayers 150 and 150′. The field-limitation diaphragm 152 is made of a light-impermeable material and has a plurality of specifically arranged square holes 152a, 152b, . . . 152n. A total surface area occupied by the square holes 152a, 152b, . . . 152n may reach 50-75% of the total area of the interface surface between the sublayers 150 and 150′. The geometry of the aforementioned square (or hexagonal) holes is a subject of co-pending U.S. patent application Ser. No.______filed by the same applicants on______. Exact dimensions of the diaphragms can be calculated by ray-tracing modeling taking into account specific optical characteristics of optical elements and materials from which these elements are made.

Thus, it should be noted that in the optical layer 132, the holes 140a, 140b, . . . 140n of the aperture-limitation diaphragm 140, the microlenses 144a, 144b, . . . 144n of the microlens array 144, the microlenses 148a, 148b, . . . 148n of the microlens array 148, holes 152a, 152b, . . . 152n of the field-limitation diaphragm 152, the microlenses 148a′, 148b′, . . . 148n′ of the microlens array 148′, the microlenses 144a′, 144b′, . . . 144n′ of the microlens array 144′, and the holes 140a′, 140b′, . . . 140n′ of the aperture-limitation diaphragm 140′ are mutually coaxial.

From the optical point of view, the optical layer 132 represents a thin planar objective, the total thickness of which is about 1.85 mm. In this objective, the object plane coincides with the external surface S, i.e., the surface opposite to the one in contact with the image-receiving surface S′ of the optical layer 132 (FIG. 7). A magnification factor of the objective formed by the optical layer 132 is +1X. The first half 136b of the optical layer 132 forms a certain image that is formed by a plurality of individual inverted elemental images formed by individual microlenses. It is understood that in order to form a complete non-inverted (erected) image of the object, it is necessary to invert each of the aforementioned inverted elemental images for the second time. The last-mentioned function is fulfilled by the second half 136a of the optical layer 132.

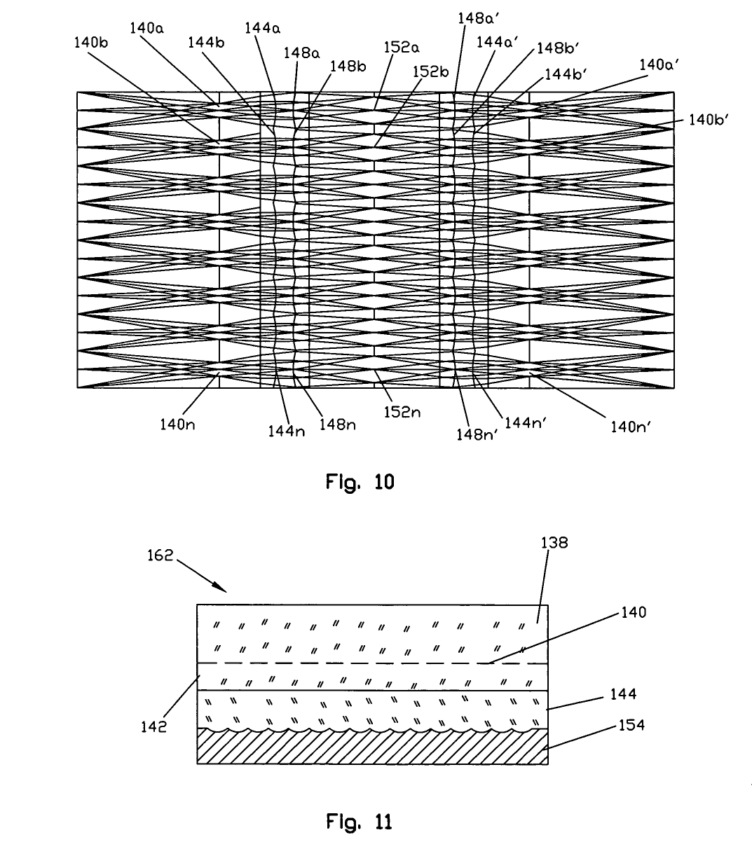

FIG. 10 shows optical paths of light rays passing through elemental optical systems formed by individual coaxially arranged holes 140a, 140b, . . . 140n, the microlenses 144a, 144b, . . . 144n, the microlenses 148a, 148b, . . . 148n, holes 152a, 152b, . . . 152n, the microlenses 148a′, 148b′, . . . 148n′, the microlenses 144a, 144b, . . . 144n, and the holes 140a′, 140b′, . . . 140n′.

Since the image sensor 130 shown in FIG. 7 is a contact-type sensor, and illumination of the surface S in contact with the object F5 is blocked for external light, the sensor 130 is provided with a laterally arranged light source.

In the embodiment of the invention shown in FIGS. 7-10, two such light sources 131a and 131b (FIG. 7) are used in the form of edge light-emitting diodes. It is understood that two or four such light sources should be provided for a square-shaped sensor. The thickness of such edge light-emitting diodes should not exceed the thickness of the sublayer 138′ (FIG. 8) in order to prevent falling of the illumination light (i.e., the light not reflected from the surface S to the image-receiving layer 134 (FIG. 7)) since this will significantly impair contrast of the reproduced image. The light emitted from the light sources 131a and 131b towards the surface S should fall on this surface at an angle that is equal to or greater than the angle α of total internal reflection. In the context of the present patent application, the angle α of total internal reflection is measured relative to the normal to the plane S (i.e., the X-Y plane). Examples of edge light-emitting diodes 131a and 131b are appropriate devices produced by Nichia Corporation, Tokushima, Japan.

The sublayers of the aforementioned optical layer 132, is structured so that the light emitted by the light sources 131a and 131b illuminates only the surface S and is prevented from falling onto the image-receiving layer 134 (FIG. 7), while only the light reflected and/or scattered from the portions of the surface S that are in contact with the object F5 can pass through the optical layer to the image-receiving layer 134, i.e., the CCD/CMOS structure.

More specifically, when the surface S (FIG. 7) is out of contact with the object, e.g., the finger F5, no image will be reproduced by the image-receiving layer 134, i.e., CCD/CMOS structure, since the incidence angle α of light falling onto the surface S is equal to or exceeds the angle of total internal reflection, as defined above. What can be received by the CCD/CMOS structure is a substantially uniformly illuminated field that will be reproduced due to multiple reflections and scattering of the light of the sources 131a and 131b in the sublayer 138′ of the optical layer 132 (FIGS. 7 and 8).

Operation—Preferred Embodiment of FIGS. 5, 7-11

When an object having a certain pattern or drawing on its surface, e.g., the finger print of a finger F5, is brought in contact with the upper surface of the optical layer 132, which is designated as the surface S, such a contact will violate uniformity of the light reflected from the surface S and scattered in the optical layer 132. Such violation of light distribution will correspond to the pattern to be reproduced on the image-receiving layer 134, e.g., on the CCD/CMOS structure. Since each microlens of the microlens arrays used in the optical layer 132 may reproduce the entire pattern, there is a danger that all individual images reproduced from each microlens in the image-receiving layer 134 will overlap each other and make it impossible to obtain an accurate image, if any. In the present invention the above problem is solved by introducing the aforementioned aperture-limitation diaphragm arrays 140 and 140′ and the field-limitation diaphragm 152. The light-impermeable areas of diaphragms arrays, i.e., the areas between the holes, are arranged so that they correspond to the areas on the image-receiving layer 134 where otherwise the images from neighboring microlenses could interfere with each other. This is achieved by appropriately selecting relative positions between the microlens arrays and diaphragms in the optical axis direction and by selecting appropriate geometry and optical characteristics of the microlenses and materials from which they are made (see pending U.S. patent application Ser. No.______files by the same applicants on______).

As a result, when an object F5 is brought in contact with the surface S that is illuminated by the lateral light sources 131a and 131b, the image-receiving layer 136 will receive an exact picture of the pattern being reproduced, e.g., a fingerprint pattern of the finger F5 (FIG. 7). In accordance with a technique known in the art, the CCD/CMOS structure 134 transmits the imager data through the data processing system, e.g., CPU (not shown) to the image recording and/or displaying units (not shown).

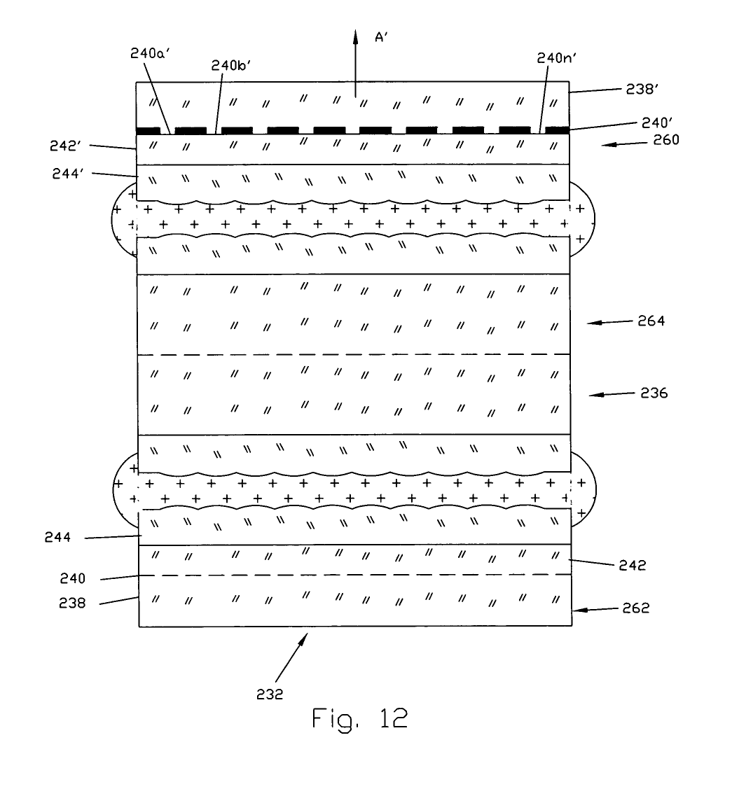

The structure of the sensor 130 that corresponds to the embodiment of the invention with lateral arrangement of light sources 131a and 131b was described in sequence that corresponds to the geometrical arrangement of the sublayers. In the manufacturing processes, the sequence of operational steps will be different and may be carried in different orders. For example, in the case of the embodiment of FIGS. 7-10, first a master die with negative images of microlens arrays 144, 148, 148′, and 144′ is produced, e.g., by methods of photolithography and dry etching. Such a master die is shown in FIG. 11 and is designated by reference numeral 154. The master die 154 can be made, e.g., from quartz or metal. The surface of the master die 154 is coated with a thin layer of a die-release agent (not shown) and then the surface is coated with a relatively thick (about 50 to 120 μm) sublayer that forms the microlens array 144, e.g., from of a chalcogenide glass (e.g., As₂S₃), e.g., by a method of thermal vacuum evaporation. The upper surface of the sublayer 144 is subjected to planarization, e.g., by chemical mechanical polishing (CMP). Planarization is carried out to a required thickness of the sublayer 144, e.g., to 100 μm. The treated upper surface of the sublayer 144 is coated with the SiO₂ sublayer 142 deposited in a sol-gel process. This process is well known in the art and described briefly, e.g., by Stefan Sinzingter, et al. in “Microoptics”, Wiley-VCH, 1999, pages 72-73. The sublayer 142 is formed to a predetermined thickness, e.g., 100 μm. If necessary, the upper surface of the sublayer 142 is planarized, and then the aperture-limitation diaphragm array 140 is formed on the surface of the sublayer 142, e.g., by a lift-off process that includes photolithography, metal sputtering, and pattern formation. If necessary, the light-impermeable portions of the diaphragm are blackened. In this case, the material for blackening is selected so that is would be compatible with the material of the diaphragm array and the process of its application. The final sublayer 138 (FIGS. 8 and 11) is applied on the diaphragm array 140, e.g., by a sol-gel process to the thickness of 380 μm. As a result, a unit 162 shown in FIG. 11 is obtained. The same unit is identical to the one composed of sublayers 144′, 142′, 140′, and 138′ of the optical layer 136 shown in FIG. 8. The unit 162 is an example of a standard modular sub-assembly that in the structure of the sensor 130 is used twice. The second use is a unit 160.

Similar processes are used for forming the structure composed of the sublayers 148, 150, and 152 and the structure of the sublayers 148′ and 150′ (FIG. 8). The structures of sublayers 148, 150, 152 and of sublayers 148′ and 150′ are assembled into an integral unit 164 by being interconnected face to face via a thin layer of an optical glue having an index of refraction close to that of silicon oxide. As a result, three separate units 160, 162, and 164, of which two (160 and 162) are external identical units and one is a central unit 164 are formed. These three units are assembled into the optical layer 136 in a compression molding process by introducing a polymer such as, e.g., polymethylmethacrylate, between the facing sides of the units for subsequent softening in the thermal compression process. If necessary, the aforementioned three units can be connected into a monolithic structure by adhesion, e.g., with the use of a UV-curable optical glue. The polymethylmethacrylate forms interface sublayers 146 and 146′ (FIG. 8) having a thickness of about 100 μm which is achieved by placing, during compression, calibrated spacers (not shown) between the mating surfaces of the sublayers of 144′, 148′ and 144, 148, respectively.

For the image sensor of the embodiment of FIGS. 7-10, it is important to maintain the surface S clean, since the contaminants left on this surface by the object after disconnection thereof from the surface S may distort the image in the subsequent image-receiving operation. Therefore, it is recommended to clean the object-contacting surface of the sensor, especially in imaging such objects as fingerprints since a finger may contaminate the surface with fatty oils, etc. that may be present on the surface of the human skin.

Preferred Embodiment of a Sensor with a Built-in Light Source—FIGS. 6, FIG. 12-16

If the image sensor is intended for use under conditions of possible contamination, it is recommended to use the image sensor made in accordance with the embodiment of the invention shown in FIG. 6, which is more stable against effect of contaminants on the contacting surface. In the embodiment of FIG. 6 a light source 122b is made in the form of a single or a multiple light-emitting diode embedded into the laminated optical layer. The structure of this sensor is shown in more detail in FIG. 12. In consideration of the embodiment of FIG. 12, the description of the parts and elements of the sensor of FIG. 12 that are identical to those described in connection with the embodiment of FIGS. 7-11 will be omitted, though their designation in FIG. 12 will be preserved and shown by the same reference numeral with an addition of 100. For example, the layer 138 will be designated as 238, the aperture-limitation diaphragm array 140 will be designated as 240, etc.

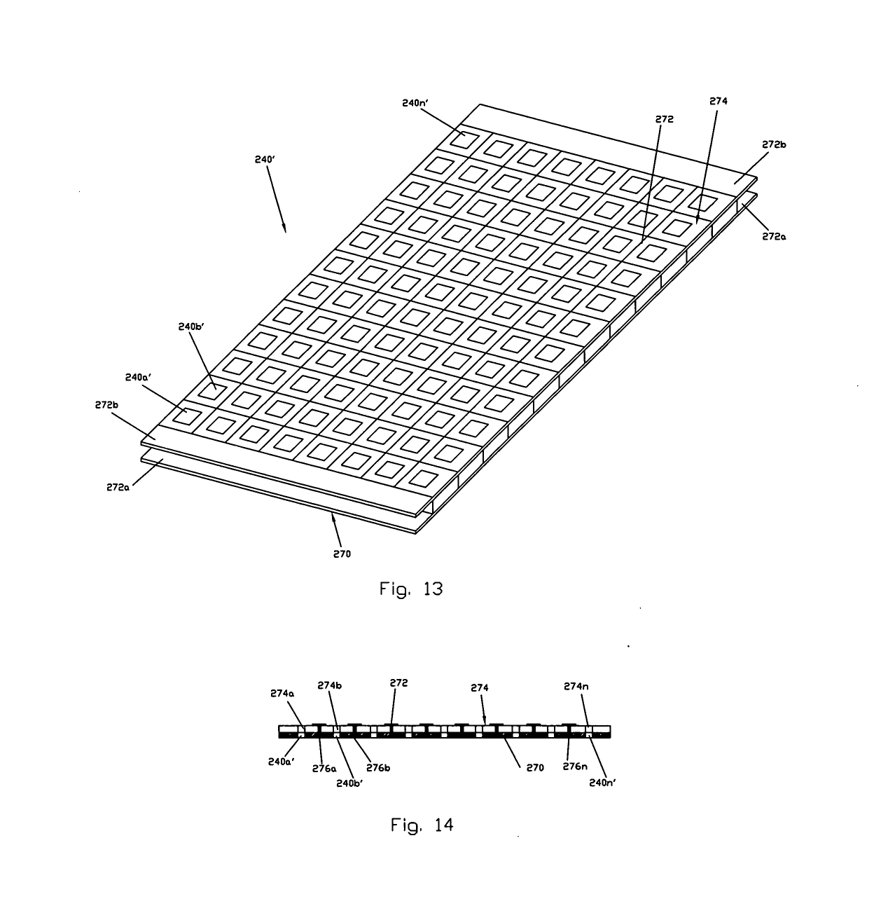

The only distinction between the embodiments of FIGS. 7-11 and FIG. 12 is the unit 260 that contains a built-in light source 122b (FIG. 6). The unit 260 consists of a microlens array sublayer 244′, which is coated with a SiO₂ sublayer 242′ formed by the aforementioned sol-gel process. In the embodiment of FIG. 12, the plain aperture-limitation diaphragm array 140′ of the previous embodiment (FIG. 8) is replaced by an aperture-limitation diaphragm array formed as a planar light source 240′ that emits light only in the direction of arrow A′ (FIG. 12). The planar light source 240′ is coated by a silicon-oxide sublayer 238′, so that the planar light source 240′ is sandwiched between the sublayers 242′ and 238′. A typical planar light source may be comprised of a light-emitting-diode (LED) structure formed on the basis of epitaxial growth described, e.g., by L. Coldren and S. Corzine in “Diode Lasers and Photonic Integrated Circuits”, issued by John Willey & Sons, Inc., N.Y., 1995, pp. 13-25. An example of such a planar light source is shown in FIG. 13, which is a three-dimensional view of the light source 240′, and in FIG. 14, which is a vertical sectional view of the light source. It is understood that the planar light source shown in FIGS. 13 and 14 is designed for an orthogonal arrangement of the aperture-limitation diaphragm array. Contacts 270 and 272 of such a structure are made as thin flat plates of the upper and lower levels, wherein the lower-level contact is 270 and the upper-level contact is 272. The lower-level contact 270 is used as a light-blocking diaphragm array with holes 240a′, 240b′, . . . 240n′ and is made as a thin metal film. Although the light-blocking diaphragms are shown with round holes, if necessary, these holes may have a square, hexagonal, or other suitable shape.

The upper-level contacts form a contact grid 272 with input terminal busses 272a, 272b that are supported by a laminated light-emitting structure 274, e.g., of InₓGa₁₋ₓAs type, epitaxially grown on the lower-level contact 270. The structure 274 or a light-emitting sublayer also has holes 274a, 274b, . . . 274n. The number of these holes is the same as in the lower-level contact 270, and they are coaxial to the respective holes of the lower level for passing the light in direction of arrow A′ and in the opposite direction through the holes of the remaining diaphragm arrays of the optical unit 232 (FIG. 12). Variations of the stoichiometric compositions of the aforementioned InₓGa₁₋ₓAs structure allows to cover the wavelength range from 0.4 μm to 2.6 μm, and the illumination light source can be conveniently selected in a desired wavelength range most suitable for specific application of the sensor. It is understood that the geometrical dimensions of the unit 232, as well as of the unit 132 (FIG. 8) of the previous embodiment, have to be interrelated with the wavelength of the selected light source used for illuminating the surface of the sensor intended for contact with the object. In order to protect the planar light source 240′, which is of a very delicate nature, from breakage and for imparting to it some flexibility, the body of the light source is divided into separate segments by cutting slots 276a, 276b, . . . 276n shown in FIG. 14. These slots are filled with a dielectric material, e.g., SiO₂. The total thickness of such a planar light source may be within the range of 10 to 20 μm, while the total thickness of the entire image sensor may have a thickness not exceeding 2.5 mm.

Although in FIGS. 13 and 14 the linear contacts 272 and the slots 276a, 276b, . . . 276n are shown as the same lines, in the actual structure the contacts will be arranged in the slots on both side of the slot-filling material.

Operation and Manufacturing Processes—Preferred Embodiment of FIGS. 6, 12-16

When a DC voltage of 1.5 to about 3.6 V is applied to the input terminal busses 272a, 272b, the InₓGa₁₋ₓAs structure begins to emit light that propagates in the direction of arrow A′. The light illuminates the back side of the transparent plate 238′ (FIG. 12) which is supposed to be in contact with the object, e.g., a finger F4 (FIG. 6). The light reflected and scatter from the object will propagate in the direction opposite to arrow A′ toward the image-receiving unit 124b (FIG. 6) via optical channels formed by the openings of the diaphragms and microlenses.

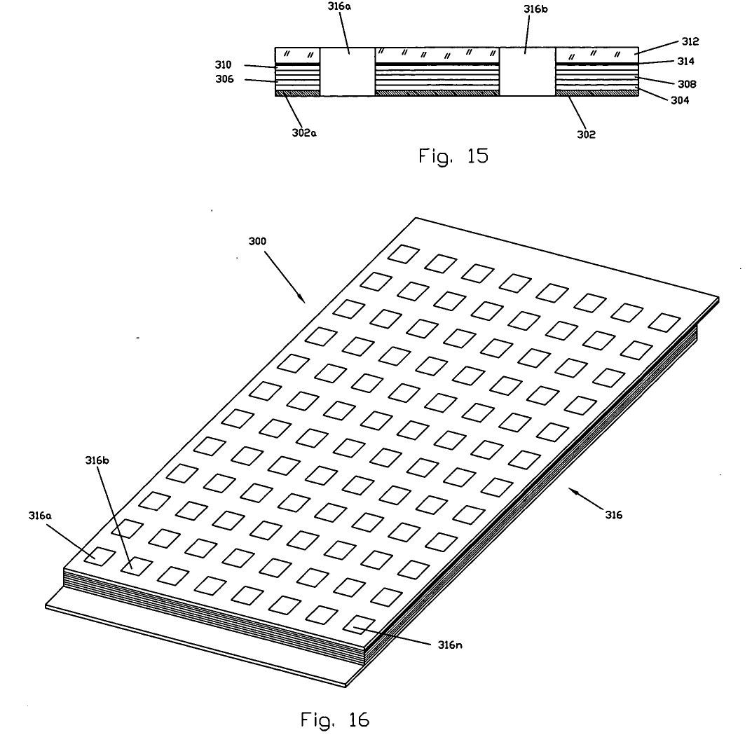

Another modification of a planar light source 300 that is based on the use of organic light-emitting diodes (OLED) is shown in FIG. 15, which is a fragmental view of the planar light source shown in cross section. As can be seen from FIG. 15, the planar light source 300 has a laminated structure consisting of the layers described below and listed in the direction of arrow A2 staring from the layer 242′ (FIG. 12), onto which it is deposited.

A first layer 302 is a metallic cathode made, e.g., of copper, having a thickness not exceeding 10 μm. The backside 302a of this layer is blackened in order to exclude flares on microlenses. Second, third, fourth, and fifth layers are an electron injection layer 304, electron transfer layer 306, emission material layer 308, and hole-transfer layer 310, respectively. These layers have fluorescent thin films made from organic materials with specific electro-physical properties (see Samsung SDI—Technology Driven Co.; http://www.samsungsdi.co.kr). These layers are coated with the sixth layer that is a protective glass layer 312 via a transparent electrically-conductive indium-tin oxide (ITO) layer 314. The latter is sandwiched between the protective glass layer 312 and the hole-transfer layer 310. In the structure of FIG. 15, the ITO layer 314 functions as an anode.

When a voltage signal that may have a value of about 1.4 to 4.5 V is applied between the cathode 302 and anode 314, the organic materials begin to emit light in the direction of arrow A2 (FIG. 15) that propagates through the glass layer 312 and the transparent conductive anode layer 314.

Similar to the embodiment with the built-in light source shown in FIGS. 12-14, the laminated structure of FIG. 15 has an aperture-limitation diaphragm array 316 formed by holes 316a, 316b, . . . 316n. FIG. 16 is a three-dimensional view on a part of the light source formed by the structure of FIG. 15. In the example shown in FIG. 16, the diaphragm holes have orthogonal arrangement. Such an arrangement should coincide with the arranged of microlenses and holes of the diaphragms. It is understood that the orthogonal arrangement is shown only as an example and that the holes may have a hexagonal arrangement as well. Preferably, the area of the diaphragm 316 occupied by the holes 316a, 316b, . . . 316n should not exceed 30%. It should be note that although the diaphragm holes of this embodiment are shown as round openings, these openings may have a square, hexagonal or another suitable shape.

Each of the aforementioned organic layers 304-310 does not exceed several hundred Angstroms. The ITO layer 314 may have a thickness, e.g., of 1000 to 2000 Angstroms. The protective layer 312 may have a thickness of about 20 μm. Thus, the total thickness of the laminated structure of FIG. 15 is determined by the thickness of the cathode layer 302 and the glass protective layer 312 and may not exceed 25 to 30 μm.

The remaining parts of the monolithic optical image sensors of the embodiment with the OLED-type light source of FIG. 15, including the silicon-oxide sublayer 238′ shown in FIG. 12, remain the same as the one shown in FIG. 6 and 12, except that the thickness of the light source should be corrected by changing the thickness of the silicon-oxide sublayer 238′ shown in FIG. 12. It is understood that the silicon-oxide sublayer 238′ may be made integrally with the structure of FIG. 15.

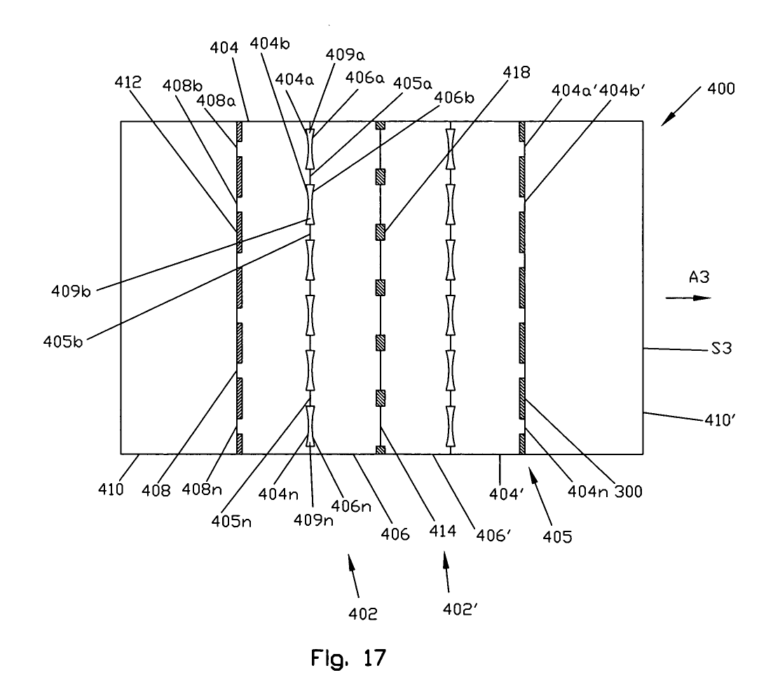

Description—Alternative Embodiment—FIGS. 17-21

FIG. 17 is a sectional view of an optical layer 400 used in a thin monolithic image sensor that has a simplified construction and is less expensive to manufacture. This is because all the sublayers of the entire optical layer 400 are made by injection molding or thermal compression molding substantially from a single material, e.g., polycarbonate. The thermal compression molding process suitable for the present invention is described, e.g., y by Stefan Sinzingter, et al. in the aforementioned book entitled “Microoptics”, Wiley-VCH, 1999, pages 70-73. Similar to the structure of FIG. 12, the optical layer 400 of FIG. 17 has a laminated structure composed of two optically identical pairs of modular units 402 and 402′. Each pair of the modular units is manufactures by similar methods with the use of the same pressure-molding or injection-molding dies (not shown). Therefore, only one of these units (402) will be considered below.

The unit 402 consists of a microlens array 404 and a microlens array 406. Microlenses 404a, 404b, . . . 404n of the microlens array 404 are aligned with respective microlenses 406a, 406b, . . . 406n of the microlens array 406. An aperture-limitation diaphragm array 408 is molded integrally with the side of the microlens array 404 that faces the image-receiving layer 124b (FIG. 6) via a spacing polycarbonate sublayer 410.

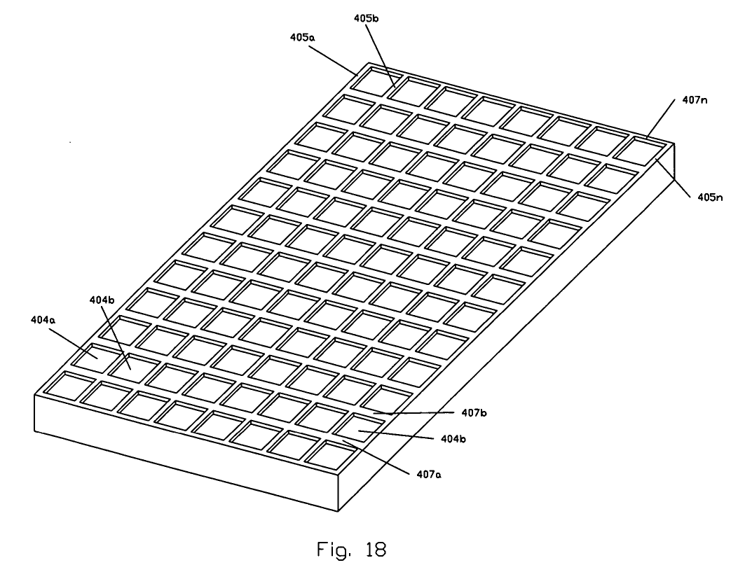

FIG. 18 is a three-dimensional view of the microlens array 404 seen from the microlens side. The embodiment of FIG. 18 illustrates an orthogonal arrangement of the microlenses 404a, 404b, . . . 404n. As can be seen from FIG. 18, the microlenses are surrounded by very narrow close-contour ridges arranged into a grid-shaped configuration. Since these are very narrow, they practically do not block efficiency of light transmission. The parallel mutually perpendicular rows 405a, 405b, . . . 405n and 407a, 407b, . . . 407n of the ridges are used for alignment with identical ridges of the microlens array 406 (not designated in the drawings) that is stacked with the microlens array 404 in a mirror-image position with respect thereto, so that spaces 409a, 409b, . . . 409n are formed between the facing microlens arrays 404 and 406. These ridges are also used for adjusting the gap between the microlenses required for proper normal operation of the optical system formed by the microlens arrays.

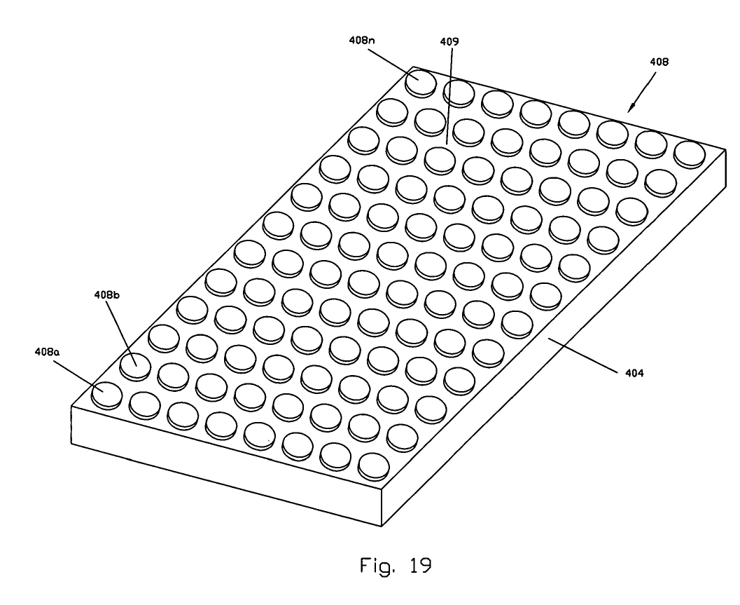

As can be seen from FIG. 19, which is a three-dimensional view of the aperture-limitation diaphragm array 408 in the direction opposite to the direction of arrow A3 (FIG. 17), the light-permeable portions of the aperture-limitation diaphragm array 408 are projecting from the body of the array 404 in the form of projections 408a, 408b, . . . 408n. The arrangement of the projections 408a, 408b, . . . 408n is also shown in FIG. 19. The remaining surface 409 between the projections is blackened for blocking passage of the light so that the light could propagate only through the projection portions. The space 412 formed between the projections 408a, 408b, . . . 408n and the surface of spacing polycarbonate sublayer 410 may be filled, e.g., with the blackening substance, such as light-impermeable dye or carbon-containing coating.

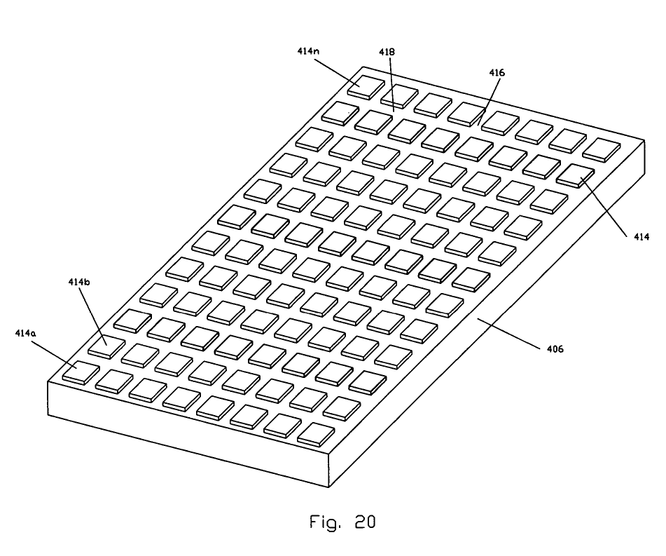

Similar to the embodiment of FIG. 12, the side of the microlens array 406 (FIG. 17) opposite to the microlenses is provided with a field-limitation diaphragm array 414, the function and structure of which were described with reference to the field limitation diaphragm array 152 of FIG. 8. Projections 414a, 414b, . . . 414n of the field-limitation diaphragm array 414 are shown in FIG. 20 and have exactly the same arrangement as the projections 408a, 408b, . . . 408n shown in FIG. 19. The only difference is that the projections 414a, 414b, . . . 414n have a square or hexagonal cross section and their surface area may occupy up to 70% of the total surface area of the field-limitation diaphragm array 414. More specifically, if the microlens arrays have an orthogonal arrangement, the field-limitation diaphragm array 414 also should have an orthogonal arrangement, and the diaphragm openings should have a square shape. Similarly, if the microlens arrays have a hexagonal arrangement, the field-limitation diaphragm array 414 also should have a hexagonal arrangement and the diaphragm openings should have a hexagonal shape.

The surface 416 between the projections 416a, 416b, . . . 416n is blackened for blocking the passage of the light through the areas between the projections 414a, 414b, . . . 414n. A space 418 formed between projections 416a, 416b, . . . 416n is filled with a light-impermeable and, preferably, light-absorbing material such as carbon-containing dye, or the like.

The microlens array 404 (FIG. 17) and microlens array 406 are applied onto each other face to face with their mutually perpendicular rows 405a, 405b, . . . 405n and 407a, 407b, . . . 407n of the ridges being aligned (FIG. 18). In this position, the microlens array 404 and microlens array 406 are glued together via a thin optical glue layer that may have a thickness of about 1.5-2.0 μm. In this embodiment, the optical glue should have an index of refraction close to that of polycarbonate. Thus the aforementioned unit 402 is formed.

The optical unit 402′ (FIG. 17) is absolutely identical to the optical unit 402. In order to form a monolithic optical layer 400, such as layer 124b of FIG. 6, the optical units 402 and 402′ should be combined and connected face to face with each other in a mirror-image arrangement with alignment of respective microlenses and diaphragms. The units are connected by gluing via a thin optical glue layer having a thickness of 1.5-2.0 μm.

The side of the optical layer 400 that faces the image-receiving unit 124b (FIG. 6) is coated with the polycarbonate spacer 410 (FIG. 17), which is glued to the microlens array 404.

The side of the optical layer 400 opposite to the polycarbonate spacer 410 is assembled with the planar light source 300 (FIG. 16) by inserting the projections 404a′, 404b′, . . . 404n′ (FIG. 17) on the back side of the microlens array 404′ into the respective holes 316a, 316b, . . . 316n of the planar light source 300 so that the optical layer 400 is aligned with the planar light source 300. The assembled parts are interconnected via an optical glue. The back side of the planar light source 300 is then covered with a polycarbonate optical spacer 410′. Thus the optical layer 400 of the image sensor 120b shown in FIG. 6 is completed. The surface S₃ of the assembled optical layer 400 is the one that is intended for contact with the object, e.g., a finger Fb for taking an image of the fingerprint.

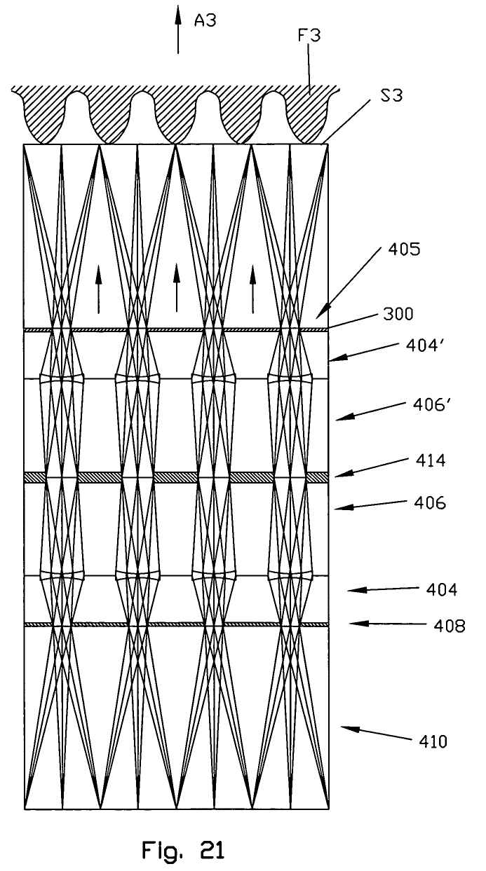

FIG. 21 shows optical paths of light rays passing through the laminated optical layer 400, where the light propagates from the planar light source 300 towards the surface S3 in the direction of arrow A3, while the light reflected from the surface S3 in contact with the finger Fb (FIG. 6) propagates through microlens arrays 406′, aperture limitation diaphragm array 405, the microlens array 404, the microlens array 406, field limitation diaphragm array 414, microlens array 406, microlens array 404, and aperture limitation diaphragm array 408 (FIG. 21) towards the image-receiving unit 124b (FIG. 6)

It is understood that the major elements of the laminated structure 400 described with reference to FIGS. 6, 14-21 may be applicable to the embodiment of FIG. 5 and FIG. 7 with edge light sources 131a and 131b.

An image sensor that incorporates the optical layer of the type shown in FIGS. 17-21 operates in the same manner as the one disclosed with reference to FIGS. 5, 7-10.

Thus, it has been shown that the invention provides a thin flat monolithic image sensor that has a thickness reduced to the dimension unattainable in conventional flat image sensors and that allows insertion of the sensor into the slot of an automatic banking teller machine. The sensor of the invention has a thin-layered laminated structure that consists of an optical layer and an image-receiving layer, wherein the optical layer incorporates a light source for illumination of the sensor's surface that is in contact with an object, the image of which is to be reproduced. A unique feature of the sensor of the invention is that light emitted by the light source, which has a lateral or built-in position, propagates only towards the object, while the light reflected from the surface that is in contact with the object propagates only towards the light-receiving layer. The aforementioned thin flat monolithic image sensor is suitable for reproducing images of fingerprints without illumination with external light. The sensor has a simplified construction and some parts of the sensor incorporate identical layers formed substantially of the same material.

Although the invention has been shown and described with reference to specific embodiments, it is understood that these embodiments should not be construed as limiting the areas of application of the invention and that any changes and modifications are possible, provided that these changes and modifications do not depart from the scope of the attached patent claims. For examples, the image sensor may be used for reproducing images of objects other than fingerprint patterns, e.g., barcodes, miniature designations, shapes of small parts on a production line, credit card data, etc. The optical layer components may be made from materials different from those mentioned in the specification. The image layers may be represented by CCD/CMOS structures of different manufacturers. The image sensors themselves may be different in shape, e.g., round, square, rectangular, etc. The light-emitting layer 240′ is not necessarily made from the InₓGa₁₋ₓAs structure and can be produced on other epitaxial structures. Although orthogonal and hexagonal openings were shown in the field-limitation diaphragm array, the openings of these configurations can also be made in the aperture-limitation diaphragm.

We Claim:

1. A contact-type monolithic image sensor for obtaining an image of an object, said monolithic image sensor comprising:
an optical layer and an image-receiving layer combined into a monolithic structure, said optical layer having a first surface for contact with said object, a second surface on the side of said optical layer opposite to said first surface, and at least one side surface;
said optical layer having at least a first microlens array and a second microlens array, each containing a plurality of individual microlenses, and at least a first diaphragm array and a second diaphragm array, each said diaphragm array comprising a layer of a light-impermeable material having a plurality of individual light-permeable diaphragm openings formed in said light-impermeable material, said microlens arrays and said diaphragm arrays being arranged in different parallel planes, the number of said individual microlenses being equal to the number of said individual light-permeable diaphragm openings, said individual microlenses being coaxial to said individual light-permeable diaphragm openings.

2. The contact-type monolithic image sensor according to claim 1, further comprising at least one light source that is embedded in said optical layer and is located in a position that allows light emitted from said at least one light source to enter said optical layer through said at least one side surface and to illuminate said first surface.

3. The contact-type monolithic image sensor according to claim 1, further comprising at least one planar light source that is incorporated into said monolithic structure and is embedded into said optical layer in a position between said first surface and said first diaphragm array; said first diaphragm array being located in a position between said first surface and said first microlens array, said at least one planar light source having openings that coincide with said individual light-permeable diaphragm openings formed in said light-impermeable material.

4. The contact-type monolithic image sensor according to claim 3, wherein said second diaphragm array is located between said first microlens array and said second microlens array.

5. The contact-type monolithic image sensor according to claim 1, wherein said individual light-permeable diaphragm openings of said second diaphragm array have shapes selected from round, square, and hexagonal.

6. The contact-type monolithic image sensor according to claim 4, wherein said individual light-permeable diaphragm openings of said second diaphragm array have shapes selected from round, square, and hexagonal.

7. The contact-type monolithic image sensor according to claim 1, wherein said individual microlenses are arranged into patterns selected from an orthogonal arrangement, hexagonal arrangement or round microlenses packed in mostly dense configuration in contact with each other.

8. The contact-type monolithic image sensor according to claim 3, wherein said individual microlenses are arranged into patterns selected from an orthogonal arrangement, hexagonal arrangement or round microlenses packed in mostly dense configuration in with each other.

9. The contact-type monolithic image sensor according to claim 6, wherein said individual microlenses are arranged into patterns selected from an orthogonal arrangement, hexagonal arrangement or round microlenses packed in mostly dense configuration in with each other.

10. The contact-type monolithic image sensor according to claim 1, wherein at least a part of said optical layer is composed of at least two identical modular elements connected into a monolithic solid state structure by arranging said identical modular elements in mirror back-to-back symmetrical positions.

11. The contact-type monolithic image sensor according to claim 4, wherein at least a part of said optical layer is composed of at least two identical modular elements connected into a monolithic solid state structure by arranging said identical modular elements in mirror back-to-back symmetrical positions.

12. The contact-type monolithic image sensor according to claim 9, wherein at least a part of said optical layer is composed of at least two identical modular elements connected into a monolithic solid state structure by arranging said identical modular elements in mirror back-to-back symmetrical positions.

13. The contact-type monolithic image sensor according to claim 2, wherein said first diaphragm array being located in a position between said first surface and said first microlens array and wherein said second diaphragm array is located between sad first microlens array and said second microlens array.

14. The contact-type monolithic image sensor according to claim 13, wherein said individual light-permeable diaphragm openings of said second diaphragm array have shapes selected from round, square, and hexagonal.

15. The contact-type monolithic image sensor according to claim 14, wherein said individual microlenses are arranged into patterns selected from an orthogonal arrangement, hexagonal arrangement or round microlenses packed in mostly dense configuration in with each other.

16. The contact-type monolithic image sensor according to claim 2, wherein at least a part of said optical layer is composed of at least two identical modular elements connected into a monolithic solid state structure by arranging said identical modular elements in mirror back-to-back symmetrical positions.

17. The contact-type monolithic image sensor according to claim 13, wherein at least a part of said optical layer is composed of at least two identical modular elements connected into a monolithic solid state structure by arranging said identical modular elements in mirror back-to-back symmetrical positions.

18. The contact-type monolithic image sensor according to claim 15, wherein at least a part of said optical layer is composed of at least two identical modular elements connected into a monolithic solid state structure by arranging said identical modular elements in mirror back-to-back symmetrical positions.

19. The contact-type monolithic image sensor according to claim 1, wherein said image-receiving layer is selected from the group consisting of charge-coupled device or a complementary metal-oxide semiconductor structure.

20. The contact-type monolithic image sensor according to claim 8, wherein said image-receiving layer is selected from the group consisting of a charge-coupled device or a complementary metal-oxide semiconductor structure.

21. The contact-type monolithic image sensor according to claim 9, wherein said image-receiving layer is selected from the group consisting of a charge-coupled device or a complementary metal-oxide semiconductor structure.

22. The contact-type monolithic image sensor according to claim 13, wherein said image-receiving layer is selected from the group consisting of a charge-coupled device or a complementary metal-oxide semiconductor structure.
